(19) United States
(12) Patent Application Publication
(10) Pub. No.: US 2015/0255160 A1
(43) Pub. Date: Sep. 10, 2015

(54) MEMORY HAVING MULTIPLE SELECTABLE SPECIFICATION GRADES AND METHOD FOR OPERATING THE SAME

(71) Applicant: WUXI ADVANCE SUNRISE CO., LTD., Wuxi (CN)

(72) Inventors: Yingjiao FANG, Wuxi (CN); Ming FANG, Wuxi (CN); Jimmy LEI, Wuxi (CN)

(21) Appl. No.: 14/718,073

(22) Filed: May 20, 2015

Related U.S. Application Data
(63) Continuation-in-part of application No. 14/646,043, filed on May 20, 2015.

(30) Foreign Application Priority Data
Nov. 21, 2012 (CN) 201210473563.3

(51) Int. Cl. G11C 16/14; G11C 16/26

(52) U.S. Cl. CPC G11C 16/14; G11C 16/26

(57) ABSTRACT

A memory having multiple selectable specification grades, including: a plurality of storage bit units, control units corresponding to the storage bit units, a WL control unit for the storage bit units, and a selecting unit for controlling a memory of different specification grades. The storage bit units are regularly arrayed into row storage groups and column storage groups. Control electrodes of each row storage group are connected with one another and connected to a corresponding WL terminal. Source electrodes of the flash storage bit units of the row storage groups and the column storage groups are connected with one another and then connected to SL terminals. Drain electrodes of each column storage bit groups are connected with one another and connected to a corresponding BL terminal. The BL terminals in the column storage groups are connected to an amplifier detector via multiple paths of selectors.

### CROSS-REFERENCE TO RELATED APPLICATIONS

This application is a continuation-in-part of U.S. patent application Ser. No. 14/646,043, filed May 20, 2015, now pending, which is a National Stage Appl. filed under 35 USC 371 of International Patent Application No. PCT/CN2013/072037 with an international filing date of Mar. 1, 2013, designating the United States, now pending, and further claims priority benefits to Chinese Patent Application No. 201210473563.3 filed Nov. 21, 2012. The contents of all of the aforementioned applications, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 245 First Street, 18th Floor, Cambridge, Mass. 02142.

### BACKGROUND OF THE INVENTION

1. Field of the Invention

The invention relates to the field of the integrated circuit, and more particularly to a memory having multiple selectable specification grades and method for operating the same.

2. Description of the Related Art

Specifications of memory chips vary greatly in different uses. For example, when for military use, the reliability is highly required to ensure the product to run in harsh environments for a long time. When for civil use, priority is given to the usage cost, and the erasing times, error rates, and service life of products are not strictly required.

To meet different specification requirements, the memory manufacturers must devise corresponding production procedures and production lines, thereby increasing the production cost, reducing reusability, and prolonging the production cycle.

### SUMMARY OF THE INVENTION

In view of the above-described problems, it is one objective of the invention to provide a memory having multiple selectable specification grades and a method for operating the same. The memory of the invention has compact structure, low production cost for the chip, and security and reliability.

To achieve the above objective, in accordance with one embodiment of the invention, there is provided a memory having multiple selectable specification grades, The memory comprises: a plurality of storage bit units, control units corresponding to the storage bit units, a word line (WL) control unit for the storage bit units, and a selecting unit for controlling a memory of different specification grades. Each storage bit unit comprises: a control electrode, a source electrode, and a drain electrode. The storage bit units are regularly arrayed into row storage groups and column storage groups. Control electrodes of each row storage group are connected with one another and connected to a corresponding WL terminal. Source electrodes of the flash storage bit units of the row storage groups and the column storage groups are connected with one another and then connected to source line (SL) terminals. Drain electrodes of each column storage bit groups are connected with one another and connected to a corresponding bit line (BL) terminal. The BL terminals in the column storage groups are connected to an amplifier detector via multiple paths of selectors whereby achieving signal amplification, signal conversion, and data signal output.

In accordance with one embodiment of the invention, the WL control unit for the storage bit is a special multiplexer (MUX) for achieving word line fusion.

In accordance with one embodiment of the invention, the selecting unit is a laser fuse.

In accordance with one embodiment of the invention, the selecting unit is a nonvolatile embedded memory.

In accordance with another embodiment of the invention, there is provided with a memory having multiple selectable specification grades. The memory comprises: a plurality of storage bit units, control units corresponding to the storage bit units, a WL control unit for the storage bit units, and a selecting unit for controlling a memory of different specification grades. The selecting unit outputs a signal to select a memory of a certain specification grade. The WL control unit receives the signal output by the selecting unit to control word lines required by the certain specification grade of the memory. One, or two, or multiple corresponding word lines are synchronously controlled to achieve the selection of different specification grades of the memory.

In accordance with one embodiment of the invention, the storage bit is a flash storage bit unit.

In accordance with still another embodiment of the invention, a method for operating a memory having multiple selectable specification grades.

The memory having multiple selectable specification grades comprises: a WL control unit for the storage bit units, a selecting unit for controlling a memory of different specification grades, row storage groups, and column storage groups. Both row storage groups and column storage groups comprise a plurality of storage bit units. Control electrodes of each row storage group are connected with one another and connected to a corresponding WL terminal. Source electrodes of the flash storage bit units of the row storage groups and the column storage groups are connected with one another and then connected to SL terminals. Drain electrodes of each column storage bit groups are connected with one another and connected to a corresponding BL terminal. The BL terminals in the column storage groups are connected to an amplifier detector via multiple paths of selectors whereby achieving signal amplification, signal conversion, and data signal output.

The method for operating the memory having multiple selectable specification grades comprises: data writing operation, data reading operation, and data erasing operation.

When the selecting unit outputs a control signal for controlling the memory of different specification grades to the WL control unit for the storage bit, the control signal is used to control the memory of different specification grades. The control signal is used to control one, two, or multiple of word lines synchronously. A second operating bias voltage is loaded on SL terminals. Flash storage bit units determined by intersection of the row storage groups and the column storage groups are selected, and a first operating bias voltage is loaded on one, two, or multiple corresponding WL terminals. A third operating bias voltage is loaded on the other WL terminals. Corresponding BL terminals are selected by multiple paths of selectors, and a fourth operating bias voltage is loaded on the corresponding BL terminals. A fifth operating bias voltage is loaded on the other BL terminals.

When the first operating bias voltage, the second operating bias voltage, and the fourth operating bias voltage coordinate to allow the flash storage bit units determined by intersection of the selected BL terminals and the WL terminals to reach a voltage required for hot channel electron injection, and meanwhile the second operating bias voltage, the third operating bias voltage, and the fifth operating bias voltage coordinate to allow a voltage of the other flash storage bit units in the row storage groups and the column storage groups not to match with the voltage required for the hot channel electron injection, so as to write required data into the flash storage bit units determined by the intersection thus achieving the data writing operation of a flash memory architecture.

When the first operating bias voltage, the second operating bias voltage, and the fourth operating bias voltage coordinate to determine a value of a current passing through the flash storage bit units determined by the intersection, and meanwhile, the second operating bias voltage, the third operating bias voltage, and the fifth operating bias voltage coordinate to turn off current outputs of the other flash storage bit units in the row storage groups and the column storage groups, so as to read a storage state of the flash storage bit units determined by the intersection thus achieving the data reading operation of the flash memory architecture.

When the first operating bias voltage, the second operating bias voltage, and the fourth operating bias voltage coordinate to allow a voltage difference between the source electrode and the control electrode of the corresponding flash storage bit units connected to the first operating bias voltage to match with a required erasing voltage, and the third operating bias voltage and the fourth operating bias voltage coordinate to allow a voltage difference between the source electrode and the control electrode of the corresponding flash storage bit units connected to the third operating bias voltage not to match with the required erasing voltage, so as to store the row storage groups correspondingly connected to the first operating bias voltage thus achieving the data erasing operation of the flash memory architecture.

In a class of this embodiment, when the flash storage unit bit determined by the intersection of the row storage groups and the column storage groups is read, the first operating bias voltage is 5 V, the second operating bias voltage is 0 V, the third operating bias voltage is 0 V, the fourth operating bias voltage is 1 V, and the fifth operating bias voltage is 0 V or floating.

In a class of this embodiment, the first operating bias is loaded on two corresponding WL terminals synchronously.

In a class of this embodiment, the first operating bias is loaded on multiple corresponding WL terminals synchronously.

Advantages according to embodiments of the invention are summarized as follows:

The memory having multiple selectable specification grades of the invention comprises: a plurality of the storage bit units, the control units corresponding to the storage bit units, the WL control unit, and the selecting unit. The selecting unit outputs a signal to select a memory of a certain specification grade. The WL control unit receives the signal output by the selecting unit to control word lines required by the certain specification grade of the memory. One, or two, or multiple corresponding word lines are synchronously controlled to achieve the selection of different specification grades of the memory. Thus, the memory having multiple selectable specification grades of the invention is applicable to systems of different specification grades. In addition, the memory of the invention has reduced use cost, shortened duration from the finished product to application in the market, and wide application range.

### BRIEF DESCRIPTION OF THE DRAWINGS

The invention is described hereinbelow with reference to the accompanying drawings, in which:

FIG. 1 is a structure diagram of a memory having multiple selectable specification grades in accordance with one embodiment of the invention;

FIG. 2 is a structure diagram of multiple storage bit units in row storage groups and column storage groups in accordance with one embodiment of the invention;

FIG. 3 is a MUX in accordance with one embodiment of the invention;

FIG. 4 is a logic schematic diagram of a MUX in accordance with one embodiment of the invention; and

FIG. 5 is a logic module formed by combining a MUX and a specific 32×32 memory module in accordance with one embodiment of the invention.

In the drawings, the following reference numbers are used: 200. Memory having multiple selectable specification grades; 201. Selecting unit for controlling a memory of different specification grades; 203. Storage bit units; 202. Control units corresponding to storage bit units; 202a. MUX; and 202b. Logic schematic diagram of MUX.

### DETAILED DESCRIPTION OF THE EMBODIMENTS

For further illustrating the invention, experiments detailing a memory having multiple selectable specification grades and a method for operating the same are described below. It should be noted that the following examples are intended to describe and not to limit the invention.

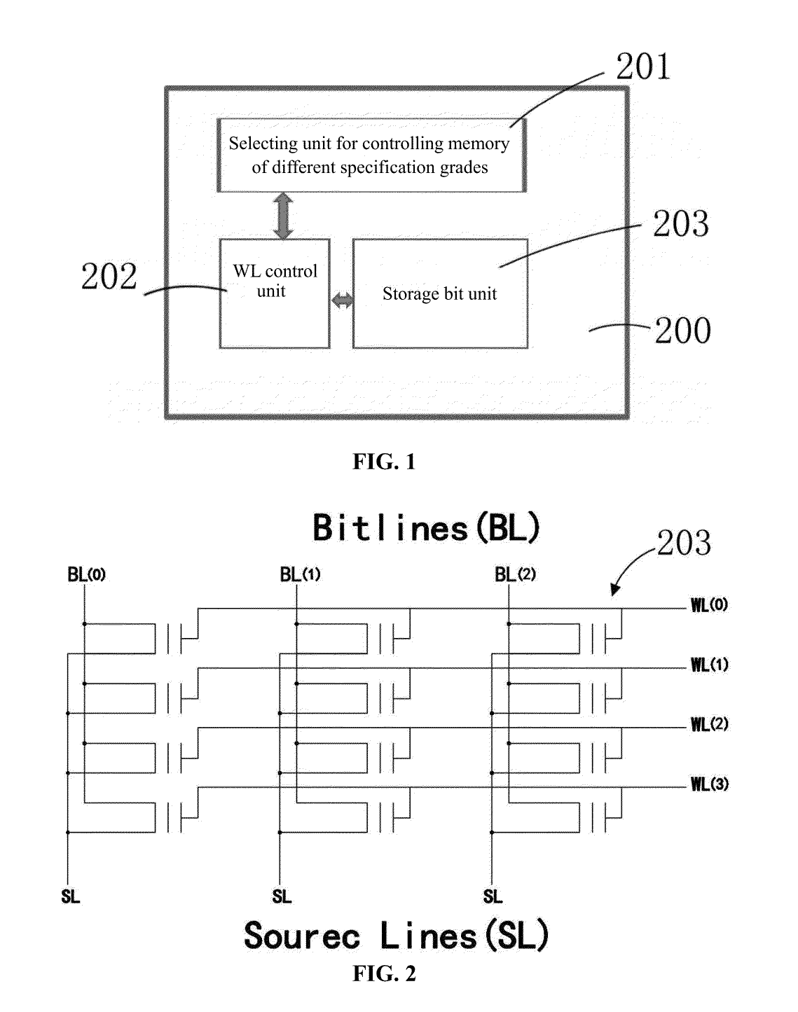

A memory product having a single bit is generally based on the specification of one word line controlling the activity of one bit, as shown in FIG. 1. In general, a data control signal is capable of controlling an “on” state and an “off” state. A primary principle of the invention is that a control signal is sent to control one or multiple word lines at any time flexibly according to requirements of clients. The control signal is achieved by a MUX. This is the extension of the control signal. The control of one word line and the control of two word lines are taken as examples for explaining the above principle.

Assuming when the control signal is 0, only one word line is each clock section of a chip can be opened or controlled, and then only one unit bit in each memory cell works. When the control signal is 1, two word lines are turned on or controlled at the same time, which means two unit bits in each memory cell work. Thus, the same operations are performed in the two unit bits, and one hundred percent redundancy effect is achieved. Even one unit bit is dysfunctional, the stored data of each memory cell cannot be damaged because another unit bit still works normally. Thus, the reliability of the chip is largely improved.

When only one unit bit in each memory cell works, the memory can only operates at between −40° C. to 85° C. to ensure an error rate of the memory below 0.1%. When working environment of the memory is commercial use (the temperature of between −40° C. to 125° C.), or in military industry and automobile industry (the temperature of between −40° C. to 150° C.), the error rate of the chip largely increases, which nearly reaches 5% and leads to that a large amount of documents are damaged and not readable. In such circumstance, the two unit bits are used to perform the same applications whereby achieving one hundred percent redundancy. Although the error rate of a single logic gate of the chip remains the same, the probability for dysfunction of all the unit bits (two or multiple) in the same memory cell is much lower than 0.1%. Thus, the same reliability can be achieved in much harsher environment.

Despite the fact that the storage capacity of the memory is decreased for a half under the same chip area, the typical commercial or military products pay more attention to the reliability of the product while has relatively low requirements on the capacity of the memory. Military products satisfying both the capacity and the reliability can be produced on the civil production line. In the other respect, the product adopting the invention is adaptable to two or multiple markets (the civil market, the industrial market, or the military market) for different demands, thereby largely decreasing the costs for design and production and shortening the duration from the finished product to application in the market.

As shown in FIG. 1, a memory 200 having multiple selectable specification grades comprises: a plurality of storage bit units 203, control units 202 corresponding to the storage bit units, a WL control unit for the storage bit units, and a selecting unit 201 for controlling a memory of different specification grades.

As shown in FIG. 2, a structure diagram of the storage bit units 203 comprises 12 bit units which are arrayed into four rows and three columns. Row storage group and column storage groups both comprise a plurality of storage bit units 203. Control electrodes of each row storage group are connected with one another and connected to a corresponding WL terminal, thereby forming four word lines for storage bit units. Source electrodes of the flash storage bit units in the row storage groups and the column storage groups are connected to one another and then connected to SL terminals, and drain electrodes of each column storage group are connected with one another and then connected to a corresponding bit line terminal, so that three bit lines and three source lines are formed.

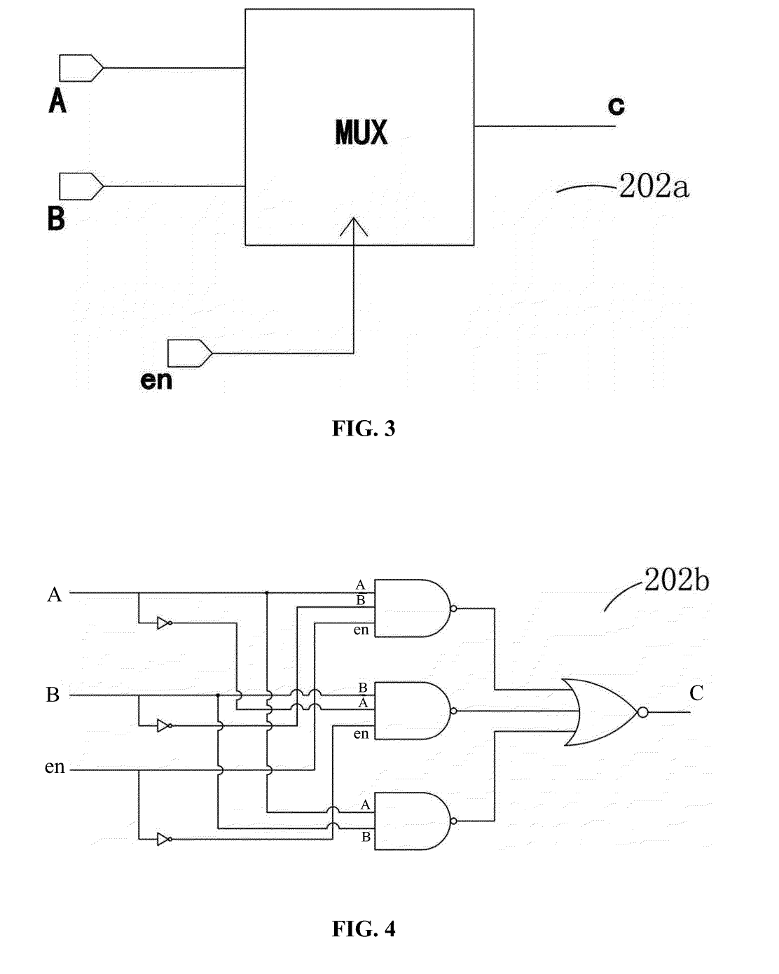

As shown in FIGS. 3-4, two or more word lines are controlled by a MUX 202a. Herein the control of two word lines is taken as an example. When a control signal en is 0, an output signal C is equivalent to an input signal B, while when the control signal en is 1, the output signal C is equivalent to the input signal A. That is, if the memory chip is used by civilian customers, the en is set to be 0, and A and B are used to control different memory cell modules; and if the memory chip is used commercially or militarily, en is set to be 1, and the input signal A controls the two memory modules originally controlled by A and B.

FIG. 4 is a logic schematic diagram for specifically achieving the signal C.

C=Ā×B× e̅n̅+A× B̅×en+A×B

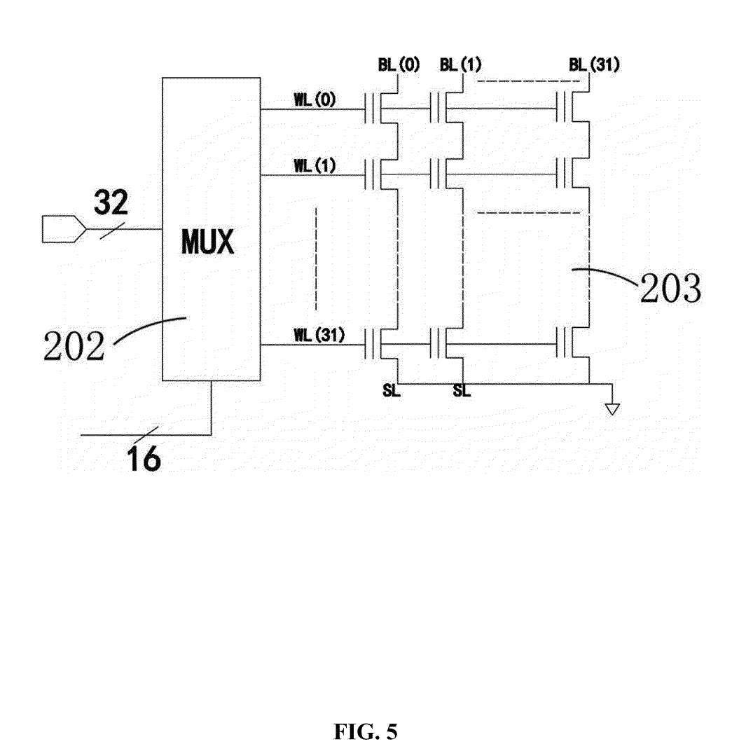

As shown in FIG. 5, the MUX and a specific 32×32 memory module are combined together to form a logic module.

The memory chip of the invention in the industry standard is not supposed to be mounted with pins after the package. In order to satisfy the industry standard and be consistent to the pins of memory chips provided by other manufacturers, the control signal of the invention is realized by regulating internal fuse or e-fuse in the physical connecting mode before the chip encapsulation. After the encapsulation, the terminal users are unable to regulate the internal fuse or e-fuse from outside the package. For example, when the chip is applied to civil use, the fuse or e-fuse is programmed into the corresponding value, i. e., 0. When the chip is applied to military use, the fuse or e-fuse is programed into other corresponding value, i. e., 1, whereby achieving the redundancy purpose. Similarly, the signal is able to control corresponding word lines.

A single flash storage bit unit comprises: a control electrode, a drain electrode, a source electrode, and a floating gate electrode. When a corresponding voltage is loaded, data writing, data reading, and data operation are realized on the single flash storage bit unit. When a plurality of flash storage bit units are regularly arranged into row storage groups and column storage groups, the single flash storage bit unit among the row storage groups and column storage groups is specifically operated as follows:

A method for operating the flash storage bit unit in the row storage groups and the column storage groups comprises: data writing, data reading, and data erasing.

A second operating bias voltage is loaded on SL terminals. Flash storage bit units determined by intersection of the row storage groups and the column storage groups are selected, and a first operating bias voltage is loaded on one, two, or multiple corresponding WL terminals. A third operating bias voltage is loaded on the other WL terminals. Corresponding BL terminals are selected by multiple paths of selectors, and a fourth operating bias voltage is loaded on the corresponding BL terminals. A fifth operating bias voltage is loaded on the other BL terminals. The fourth operating bias voltage and the fifth operating bias voltage are loaded after selection by the multiple paths of selectors and determination of corresponding voltages.

When the first operating bias voltage, the second operating bias voltage, and the fourth operating bias voltage coordinate to allow the flash storage bit units determined by intersection of the selected BL terminals and the WL terminals to reach a voltage required for hot channel electron injection, and meanwhile the second operating bias voltage, the third operating bias voltage, and the fifth operating bias voltage coordinate to allow a voltage of the other flash storage bit units in the row storage groups and the column storage groups not to match with the voltage required for the hot channel electron injection, so as to write required data into the flash storage bit units determined by the intersection thus achieving the data writing operation of a flash memory architecture.

When the first operating bias voltage, the second operating bias voltage, and the fourth operating bias voltage coordinate to determine a value of a current passing through the flash storage bit units determined by the intersection, and meanwhile, the second operating bias voltage, the third operating bias voltage, and the fifth operating bias voltage coordinate to turn off current outputs of the other flash storage bit units in the row storage groups and the column storage groups, so as to read a storage state of the flash storage bit units determined by the intersection thus achieving the data reading operation of the flash memory architecture.

When the first operating bias voltage, the second operating bias voltage, and the fourth operating bias voltage coordinate to allow a voltage difference between the source electrode and the control electrode of the corresponding flash storage bit units connected to the first operating bias voltage to match with a required erasing voltage, and the third operating bias voltage and the fourth operating bias voltage coordinate to allow a voltage difference between the source electrode and the control electrode of the corresponding flash storage bit units connected to the third operating bias voltage not to match with the required erasing voltage, so as to store the row storage groups correspondingly connected to the first operating bias voltage thus achieving the data erasing operation of the flash memory architecture.

Operating bias voltage voltages are specifically as follows: when the flash storage unit bit determined by the intersection of the row storage groups and the column storage groups is read, the first operating bias voltage is 5 V, the second operating bias voltage is 0 V, the third operating bias voltage is 0 V, the fourth operating bias voltage is 1 V, and the fifth operating bias voltage is 0 V or floating.

When the flash storage unit bit determined by intersection of the row storage groups and the column storage groups is written, the first operating bias voltage is 9 V, the second operating bias voltage is 0 V, the third operating bias voltage is 0 V, the fourth operating bias voltage is 5 V, and the fifth operating bias voltage is 0 V.

When the flash storage unit bit determined by intersection of the row storage groups and the column storage groups is erased, the first operating bias voltage is −9 V, the second operating bias voltage is 9 V, the third operating bias voltage is 0 V, and both the fourth operating bias voltage and the fifth operating bias voltage are floating.

When the first operating bias voltage of 5 V is loaded on the corresponding WL terminals, the third operating bias voltage of 0 V is loaded on other WL terminals, the second bias voltage of 0 V is loaded on the SL terminals, the BL terminals chosen by the multiple paths of the selectors are loaded with voltages of 1 V, and the other BL terminals are loaded with voltage of 0 V or is floating. When data are previously written into the flash storage bit units determined by the BL terminals and the WL terminals, the read data are stored in the floating gate electrodes where no current or only a small current passes under the corresponding cooperation of the first operating bias voltage, the second operating bias voltage, and the fourth operating bias voltage. When the flash storage bit units are in the erasing state previously, no electron, a small amount of electrons, or positive ions are stored in the floating gate electrodes. And under the cooperation of the first operating bias voltage, the second operating bias voltage, and the fourth operating bias voltage, a relatively large current passes through the floating gate electrodes, so that the control signal “1” or “0” stored in the flash storage bit units can be distinguished by signal amplification and conversion by a local sense amplifier and a global sense amplifier, so that the data reading operation of the flash storage bit units in the row storage groups and the column storage groups is realized.

In condition that the first operating bias voltage of 9 V is loaded on the WL terminals, the third operating bias voltage of 0 V is loaded on other WL terminals, the second bias voltage of 0 V is loaded on the SL terminals, the fourth bias voltage of 5 V is loaded on the selected BL terminals, and the fifth bias voltage of 0 V is loaded on the other BL terminals, and under the cooperation of the first operating bias voltage, the second operating bias voltage, and the third operating bias voltage, electrons pass through silicon dioxide to enter the floating gate electrodes by the hot channel electron injection. The hot channel electron injection is considered to be the commonly used writing operation in processing for achieving the data writing of the single flash storage bit unit. Meanwhile, the flash storage bit units connected to the third operating bias voltage and the fifth operating bias voltage cannot match with the required voltage for the hot channel electron injection, writing operations cannot be performed on these flash storage bit units, thereby being prevented from disturbing data writing of other flash storage bit units.

In condition that the first operating bias voltage of −9 V is loaded on the WL terminals, the third operating bias voltage of 0 V is loaded on other WL terminals, the second bias voltage of 9 V is loaded on the SL terminals, and both the fourth bias voltage and the fifth bias voltage are floating voltages, under the cooperation of the first operating bias voltage and the second operating bias voltage, the electric field required for the Fowler-Nordheim (FN) tunnel effect is realized, the electrons in the floating gate electrodes of the flash storage bit unit flow to the SL terminals, thereby achieving the purpose of erasing the storage from the floating gate electrodes. As the third operating bias voltage is 0 V and the voltage between the second operating bias voltage and the third operating bias voltage cannot reach the voltage value required for the FN tunnel effect, the other flash storage bit units in the row storage groups and the column storage groups cannot be erased. Because both the fourth operating bias voltage and the fifth operating bias voltage are in the floating state, the first operating bias voltage is connected to the control terminals of all the flash storage bit units in one row storage group, and the third operating bias voltage is connected to the source electrodes of all the flash storage bit units, so that all the flash storage bit units of the corresponding row storage group loaded with the first operating bias voltage are erased.

The memory having multiple selectable specification grades of the invention comprises: a plurality of the storage bit units, the control units corresponding to the storage bit units, the WL control unit, and the selecting unit. The selecting unit outputs a signal to select a memory of a certain specification grade. The WL control unit receives the signal output by the selecting unit to control word lines required by the certain specification grade of the memory. One, or two, or multiple corresponding word lines are synchronously controlled to achieve the selection of different specification grades of the memory. Thus, the memory having multiple selectable specification grades of the invention is applicable to systems of different specification grades. In addition, the memory of the invention has reduced use cost, shortened duration from the finished product to application in the market, and wide application range.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A memory having multiple selectable specification grades, comprising:
a) a plurality of storage bit units, each storage bit unit comprising: a control electrode, a source electrode, and a drain electrode;
b) control units corresponding to the storage bit units;
c) a word line (WL) control unit for the storage bit units; and
d) a selecting unit for controlling a memory of different specification grades; wherein
the storage bit units are regularly arrayed into row storage groups and column storage groups;
control electrodes of each row storage group are connected with one another and connected to a corresponding WL terminal;
source electrodes of flash storage bit units of the row storage groups and the column storage groups are connected with one another and then connected to source line (SL) terminals;
drain electrodes of each column storage bit groups are connected with one another and connected to a corresponding bit line (BL) terminal; and
BL terminals in the column storage groups are connected to an amplifier detector via multiple paths of selectors whereby achieving signal amplification, signal conversion, and data signal output.

2. The memory structure of claim 1, wherein the WL control unit for the storage bits is a special multiplexer (MUX) for achieving word line fusion.

3. The memory structure of claim 1, wherein the selecting unit is a laser fuse.

4. The memory structure of claim 1, wherein the selecting unit is a nonvolatile embedded memory.

5. A memory having multiple selectable specification grades, the memory comprising:
a) a plurality of storage bit units;
b) control units corresponding to the storage bit units;
c) a WL control unit for the storage bit units; and
d) a selecting unit for controlling a memory of different specification grades; wherein
the selecting unit outputs a signal to select a memory of a certain specification grade;
the WL control unit receives the signal output by the selecting unit to control word lines required by the certain specification grade of the memory; and
one, or two, or multiple corresponding word lines are synchronously controlled to achieve the selection of different specification grades of the memory.

6. The memory of claim 5, wherein the storage bit is a flash storage bit unit.

7. A method for operating a memory having multiple selectable specification grades, the memory comprising:
a) a WL control unit for the storage bit units;
b) a selecting unit for controlling a memory of different specification grades;
c) row storage groups; and
d) column storage groups;
both row storage groups and column storage groups comprising a plurality of storage bit units;
wherein
control electrodes of each row storage group are connected with one another and connected to a corresponding WL terminal;
source electrodes of the flash storage bit units of the row storage groups and the column storage groups are connected with one another and then connected to SL terminals;
drain electrodes of each column storage bit groups are connected with one another and connected to a corresponding BL terminal; and
the BL terminals in the column storage groups are connected to an amplifier detector via multiple paths of selectors whereby achieving signal amplification, signal conversion, and data signal output;
the method comprising: data writing operation, data reading operation, and data erasing operation;
wherein
when the selecting unit outputs a control signal for controlling the memory of different specification grades to the WL control unit for the storage bit, the control signal is used to control the memory of different specification grades; the control signal is used to control one, two, or multiple of word lines synchronously;
a second operating bias voltage is loaded on SL terminals; flash storage bit units determined by intersection of the row storage groups and the column storage groups are selected, and a first operating bias voltage is loaded on one, two, or multiple corresponding WL terminals; a third operating bias voltage is loaded on the other WL terminals; corresponding BL terminals are selected by multiple paths of selectors, and a fourth operating bias voltage is loaded on the corresponding BL terminals; and a fifth operating bias voltage is loaded on the other BL terminals;
when the first operating bias voltage, the second operating bias voltage, and the fourth operating bias voltage coordinate to allow the flash storage bit units determined by intersection of the selected BL terminals and the WL terminals to reach a voltage required for hot channel electron injection, and meanwhile the second operating bias voltage, the third operating bias voltage, and the fifth operating bias voltage coordinate to allow a voltage of the other flash storage bit units in the row storage groups and the column storage groups not to match with the voltage required for the hot channel electron injection, so as to write required data into the flash storage bit units determined by the intersection thus achieving the data writing operation of a flash memory architecture;
when the first operating bias voltage, the second operating bias voltage, and the fourth operating bias voltage coordinate to determine a value of a current passing through the flash storage bit units determined by the intersection, and meanwhile, the second operating bias voltage, the third operating bias voltage, and the fifth operating bias voltage coordinate to turn off current outputs of the other flash storage bit units in the row storage groups and the column storage groups, so as to read a storage state of the flash storage bit units determined by the intersection thus achieving the data reading operation of the flash memory architecture;
when the first operating bias voltage, the second operating bias voltage, and the fourth operating bias voltage coordinate to allow a voltage difference between the source electrode and the control electrode of the corresponding flash storage bit units connected to the first operating bias voltage to match with a required erasing voltage, and the third operating bias voltage and the fourth operating bias voltage coordinate to allow a voltage difference between the source electrode and the control electrode of the corresponding flash storage bit units connected to the third operating bias voltage not to match with the required erasing voltage, so as to store the row storage groups correspondingly connected to the first operating bias voltage thus achieving the data erasing operation of the flash memory architecture.

8. The method of claim 7, wherein when a flash storage unit bit determined by the intersection of the row storage groups and the column storage groups is read, the first operating bias voltage is 5 V, the second operating bias voltage is 0 V, the third operating bias voltage is 0 V, the fourth operating bias voltage is 1 V, and the fifth operating bias voltage is 0 V or floating.

9. The method of claim 7, wherein the first operating bias is loaded on two corresponding WL terminals synchronously.

10. The method of claim 7, wherein the first operating bias is loaded on multiple corresponding WL terminals synchronously.
